(19) United States
(12) Patent Application Publication
(10) Pub. No.: US 2025/0287795 A1
(43) Pub. Date: Sep. 11, 2025

(54) DISPLAY PANEL AND ELECTRONIC APPARATUS INCLUDING THE SAME

(71) Applicant: SAMSUNG DISPLAY CO., LTD., YONGIN-SI (KR)

(72) Inventors: EUNBYUL KIM, Yongin-si (KR); HANBUM KWON, Yongin-si (KR); YOUNGMIN AHN, Yongin-si (KR); DAEHWAN JANG, Yongin-si (KR)

(21) Appl. No.: 19/000,152

(22) Filed: Dec. 23, 2024

(30) Foreign Application Priority Data
Mar. 11, 2024 (KR) 10-2024-0033810

(51) Int. Cl. H10K 59/131

(52) U.S. Cl. CPC H10K 59/131

(57) ABSTRACT

A display panel includes pixel. A signal line is electrically connected to the pixel. A signal pad is connected to the signal line. The signal pad includes a first conductive pattern connected to an end portion of the signal line. A second conductive pattern is disposed on the first conductive pattern. An insulation pattern is disposed between the first conductive pattern and the second conductive pattern. A first through-hole is defined in the first conductive pattern. The insulation pattern extends into the first through-hole.

### CROSS-REFERENCE TO RELATED APPLICATIONS

This application claims priority under 35 U.S.C. § 119 to Korean Patent Application No. 10-2024-0033810, filed on Mar. 11, 2024 in the Korean Intellectual Property Office, the disclosure of which is incorporated by reference in its entirety herein.

### 1. TECHNICAL FIELD

Embodiments of the present disclosure herein relate to a display panel and an electronic apparatus including the same, and more particularly, to a display panel including a pad area, and an electronic apparatus including the display panel.

### 2. DISCUSSION OF RELATED ART

Display devices include display areas that are activated in response to electrical signals. The display devices may detect inputs applied from the external environment through the display areas. The display devices may also display various images to provide users with visual information.

The display devices include display panels and circuit boards. The display panels may be electrically connected to main boards through the circuit boards. Driving chips may be mounted on the display panels.

### SUMMARY

Embodiments of the present disclosure provides a display panel with increased bonding reliability, and an electronic apparatus including the display panel.

According to an embodiment of the present inventive concept, a display panel includes pixel. A signal line is electrically connected to the pixel. A signal pad is connected to the signal line. The signal pad includes a first conductive pattern connected to an end portion of the signal line. A second conductive pattern is disposed on the first conductive pattern. An insulation pattern is disposed between the first conductive pattern and the second conductive pattern. A first through-hole is defined in the first conductive pattern. The insulation pattern extends into the first through-hole.

In an embodiment, an entirety of the insulation pattern may be disposed inside each of the first conductive pattern and the second conductive pattern on a plane.

In an embodiment, the second conductive pattern may directly contact a first portion of the first conductive pattern that does not overlap the insulation pattern on a plane and a top surface of the insulation pattern.

In an embodiment, the first through-hole may overlap the insulation pattern on a plane.

In an embodiment, the insulation pattern may include a polymer.

In an embodiment, the display panel may further include a pad insulation layer disposed between the end portion of the signal line and the first conductive pattern. A second through-hole extending from the first through-hole may be defined in the pad insulation layer. The insulation pattern may extend into the second through-hole.

In an embodiment, the first through-hole may include a plurality of first through-holes.

According to an embodiment of the present inventive concept, a display panel includes a pixel. A signal line is electrically connected to the pixel. A signal pad is connected to the signal line. The signal pad includes a first conductive pattern connected to an end portion of the signal line. A second conductive pattern is disposed on the first conductive pattern. An insulation pattern in which an entirety of the insulation pattern is disposed inside each of the first conductive pattern and the second conductive pattern on a plane. The insulation pattern includes a first portion disposed between the first conductive pattern and the second conductive pattern. A second portion protrudes from the first portion in a direction away from an upper surface of the second conductive pattern.

In an embodiment, a first through-hole may be defined in the first conductive pattern, and the second portion of the insulation pattern may be disposed inside the first through-hole.

In an embodiment, the second conductive pattern may directly contact a first portion of the first conductive pattern that does not overlap the insulation pattern on a plane and a top surface of the insulation pattern.

In an embodiment, the insulation pattern may include a polymer.

In an embodiment, the first through-hole may overlap the insulation pattern on a plane.

In an embodiment, the display panel may further include a pad insulation layer disposed between the end portion of the signal line and the first conductive pattern. A second through-hole extending from the first through-hole may be defined in the pad insulation layer, and the second portion of the insulation pattern may extend into the second through-hole.

In an embodiment, the first through-hole may include a plurality of first through-holes.

According to an embodiment of the present inventive concept, an electronic apparatus includes a display panel including a signal pad. An electronic component is electrically connected to the display panel. An adhesive layer bonds the display panel and the electronic component to each other. The signal pad includes a first conductive pattern having a first through-hole defined therein. A second conductive pattern is disposed on the first conductive pattern. An insulation pattern is disposed between the first conductive pattern and the second conductive pattern. The first through-hole overlaps the insulation pattern on a plane.

In an embodiment, the insulation pattern may extend into the first through-hole.

In an embodiment, an entirety of the insulation pattern may be disposed inside each of the first conductive pattern and the second conductive pattern on a plane, and the insulation pattern may include a polymer.

In an embodiment, the second conductive pattern may directly contact a first portion of the first conductive pattern that does not overlap the insulation pattern on a plane and a top surface of the insulation pattern.

In an embodiment, the electronic apparatus may further include a pad insulation layer disposed below the first conductive pattern. A second through-hole extending from the first through-hole may be defined in the pad insulation layer. The insulation pattern may extend into the second through-hole.

In an embodiment, the first through-hole includes a plurality of first through-holes.

### BRIEF DESCRIPTION OF THE DRAWINGS

The accompanying drawings are included to provide a further understanding of the present inventive concept, and are incorporated in and constitute a part of this specification. The drawings illustrate embodiments of the present inventive concept and, together with the description, serve to explain principles of the present inventive concept. In the drawings:

FIG. 1 is a perspective view of a display device according to an embodiment of the present inventive concept;

FIGS. 2A and 2B are each an exploded perspective view of a display device according to an embodiment of the present inventive concept;

FIG. 3 is a cross-sectional view of a display module according to an embodiment of the present inventive concept;

FIG. 4 is a plan view of a display panel according to an embodiment of the present inventive concept;

FIG. 5 is a cross-sectional view of a display panel illustrating a pixel according to an embodiment of the present inventive concept;

FIG. 6 is an enlarged exploded perspective view of a pad area of a display device according to an embodiment of the present inventive concept;

FIG. 7A is a schematic plan view of a pad area according to an embodiment of the present inventive concept;

FIGS. 7B and 7C are each a cross-sectional view of a pad area according to embodiments of the present inventive concept;

FIG. 8 is a cross-sectional view illustrating a bonding structure of a display device according to an embodiment of the present inventive concept; and

FIGS. 9A to 9E are each a cross-sectional view of a pad area according to embodiments of the present inventive concept.

### DETAILED DESCRIPTION OF EMBODIMENTS

It will be understood that in this specification, when an element (or region, layer, section, etc.) is referred to as being “on”, “connected to” or “coupled to” another element, it can be disposed directly on, connected or coupled to the other element or a third element may be disposed between the elements. When an element (or region, layer, section, etc.) is referred to as being “directly on”, “directly connected to” or “directly coupled to” another element, no intervening elements may be present.

Like reference numbers or symbols refer to like elements throughout. In addition, in the drawings, the thickness, the ratio, and the dimension of elements may be exaggerated for effective description of the technical contents. The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present invention, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concepts and are explained based on the direction shown in the drawing.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present inventive concept will be described with reference to the accompanying drawings.

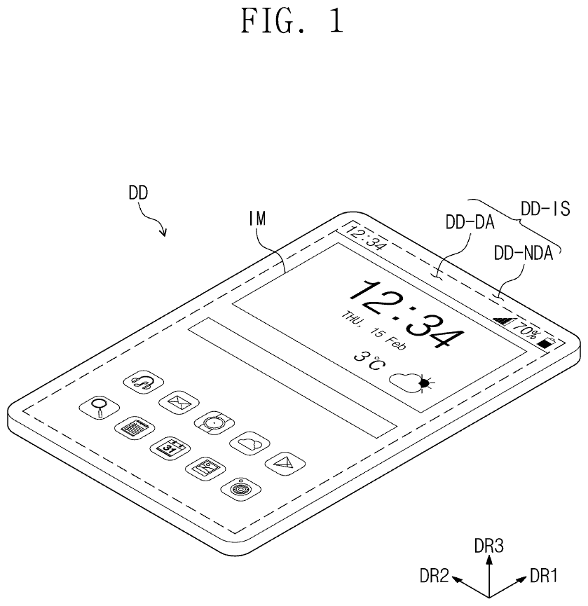

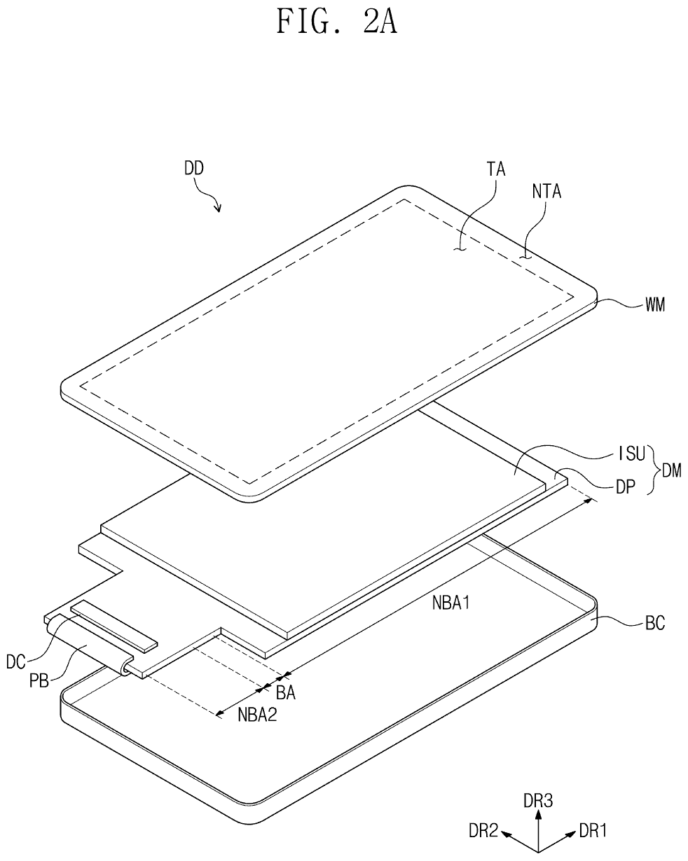

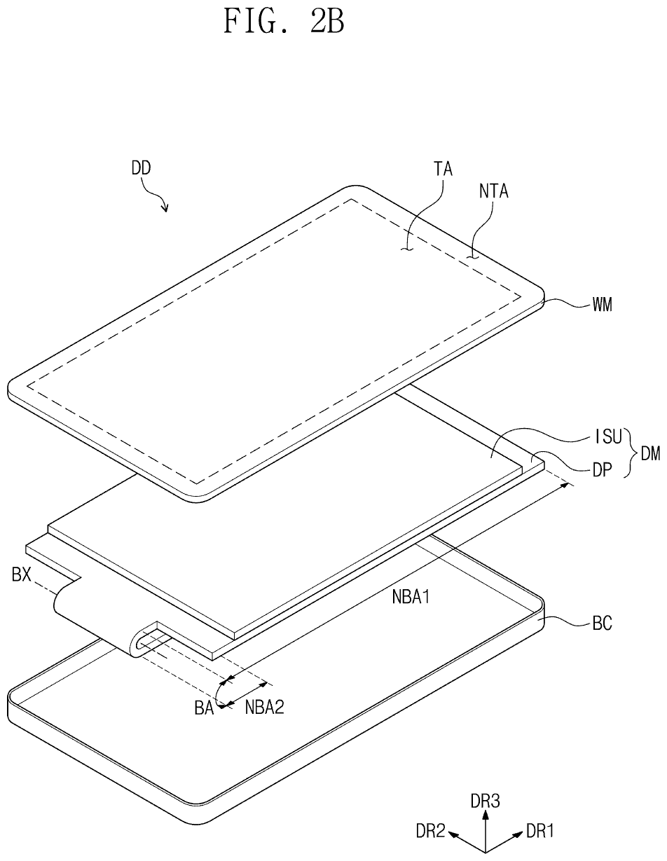

FIG. 1 is a perspective view of a display device DD according to an embodiment of the present inventive concept. FIGS. 2A and 2B are each an exploded perspective view of the display device DD according to embodiments of the present inventive concept. As an example, FIG. 2B illustrates the display device DD in a state in which a bending area BA illustrated in FIG. 2A is bent.

Referring to FIG. 1, a mobile phone terminal is illustrated as an example of the display device DD. The display device DD according to an embodiment of the present inventive concept may be applied to a large-sized electronic apparatus such as a television or a monitor, and also to a small and medium-sized electronic apparatus such as a tablet computer, a vehicle navigation unit, a game console, or a smart watch.

In an embodiment, the display device DD may have a rectangular shape having relatively long sides extending in a first direction DR1 and having relatively short sides extending in a second direction DR2 crossing the first direction DR1 on a plane. However, embodiments of the present inventive concept are not necessarily limited thereto, and the display device DD may have various shapes such as a circular shape and a polygonal shape on a plane (e.g., in a plan view).

Hereinafter, a direction substantially perpendicularly crossing a plane defined by the first direction DR1 and the second direction DR2 is defined as a third direction DR3. The state “when viewed on a plane” or “in a plan view” herein may mean a state as viewed in a third direction DR3.

The display device DD may be rigid or flexible. The term “flexible” refers to a characteristic of being capable of bending, and may include all from a fully folded structure to a structure capable of bending at the level of several nanometers. For example, in an embodiment the flexible display device DD may include a curved display device, a rollable display device, and a foldable display device.

The display device DD may display an image IM through a display surface DD-IS. In the embodiment of FIG. 1, the image IM is software application icons and a clock, temperature and calendar window. However embodiments of the present inventive concept are not necessarily limited thereto and the image IM may be various different subject matter. The display surface DD-IS may be parallel to a plane defined by the first direction DR1 and the second direction DR2.

The display surface DD-IS may include a display area DD-DA that displays the image IM, and a non-display area DD-NDA adjacent to the display area DD-DA (e.g., in the first and/or second directions DR1, DR2). The non-display area DD-NDA may be an area that does not display the image IM. However, embodiments of the present inventive concept are not necessarily limited thereto, and the non-display area DD-NDA may be adjacent to only one side of the display area DD-DA, or may be omitted.

Referring to FIGS. 2A and 2B, the display device DD may include a window WM, a display module DM, and an accommodation member BC.

The window WIN may be disposed above the display module DM (e.g., in the third direction DR3), and transmit an image provided from the display module DM to the outside (e.g., the external environment). In an embodiment, the window WIN may include a base layer and functional layers disposed on the base layer. In an embodiment, the functional layers may include a protective layer, an anti-fingerprint layer, and the like. In an embodiment, the base layer of the window WM may be made of glass, sapphire, plastic, or the like. The base layer of the window WM may include an optically transparent insulation material. For example, the base layer of the window WM may include a glass or plastic film, or include a glass substrate and a plastic film coupled to each other through an adhesive.

The window WM may include a transmission area TA and a non-transmission area NTA. The transmission area TA may overlap the display area DD-DA illustrated in FIG. 1 (e.g., in the third direction DR3), and have a shape corresponding to the display area DD-DA. The non-transmission area NTA may overlap the non-display area DD-NDA illustrated in FIG. 1 (e.g., in the third direction DR3), and have a shape corresponding to the non-display area DD-NDA. The non-transmission area NTA may be an area having a relatively low light transmittance compared to the transmission area TA. In an embodiment, the non-transmission area NTA may be defined in a partial area of the base layer of the window WM by a bezel pattern, and an area in which the bezel pattern is not disposed may be defined as the transmission area TA. However, embodiments of the present inventive concept are not necessarily limited thereto. For example, in an embodiment the non-transmission area NTA may be omitted.

In an embodiment, an anti-reflection layer may be disposed between the window WIN and the display module DM (e.g., in the third direction DR3). The anti-reflection layer may reduce reflectance of external light incident from the outside of the display device DD. In an embodiment, the anti-reflection layer may include color filters. The color filters may have a predetermined arrangement. For example, the color filters may be arranged considering emission colors of pixels included in a display panel DP to be described later. In addition, the anti-reflection layer may further include a black matrix adjacent to the color filters.

According to an embodiment of the present inventive concept, the display module DM may include the display panel DP and an input sensor ISU.

In an embodiment, the display panel DP may be any one of a liquid crystal display panel, an electrophoretic display panel, a microelectromechanical system (MEMS) display panel, an electrowetting display panel, an organic light emitting display panel, an inorganic light emitting display panel, and a quantum dot light emitting display panel. However, embodiments of the present inventive concept are not necessarily limited thereto. Hereinafter, the display panel DP is described as the organic light emitting display panel for convenience of explanation.

In an embodiment, the input sensor ISU may include any one of capacitance sensor, an optical sensor, an ultrasonic sensor, and an electromagnetic induction sensor. In an embodiment, the input sensor ISU may be formed on the display panel DP through a continuous process, or may be separately manufactured and then attached to an upper side of the display panel DP through an adhesive layer. However, the input sensor ISU is not necessarily limited to any one embodiment.

The display device DD may further include a driving chip DC disposed on the display panel DP. The display device DD may further include a circuit board PB disposed on the display panel DP. In an embodiment, the circuit board PB may be a flexible circuit board. However, embodiments of the present inventive concept are not necessarily limited thereto. For example, in an embodiment the circuit board PB may be rigid. The circuit board PB may electrically connect the display panel DP to a main circuit board.

The driving chip DC may include driving elements, for example, a data driving circuit, for driving pixels of the display panel DP. FIG. 2A illustrates a structure in which the driving chip DC is mounted on the display panel DP. However, embodiments of the present inventive concept are not necessarily limited thereto. For example, the driving chip DC may be mounted on the circuit board PB. In this embodiment, the driving chip DC and the circuit board PB that are mounted directly on the display panel DP may be collectively referred to as an electronic component.

In an embodiment, the display panel DP may include a bending area BA, and a first non-bending area NBA1 and a second non-bending area NBA2 that are arranged to be spaced apart from each other in the first direction DR1 with the bending area BA therebetween.

The bending area BA may be defined as an area in which the display panel DP is bendable along a virtual bending axis BX extending in the second direction DR2. The first non-bending area NBA1 may be defined as an area overlapping the transmission area TA (e.g., in the third direction DR3), and the second non-bending area NBA2 may be defined as an area to which the circuit board PB is connected (e.g., mounted thereto). When the bending area BA is bent around the bending axis BX, the circuit board PB and the driving chip DC may be bent in a direction towards a rear surface of the display panel DP to be disposed below the rear surface of the display panel DP. In an embodiment, the display device DD may include additional components for compensating for a height difference between the circuit board PB and the rear surface of the display panel DP, which may be generated due to the bending area BA.

According to an embodiment, a width of the first non-bending area NBA1 in the second direction DR2 may be greater than a width of each of the bending area BA and the second non-bending area NBA2 in the second direction DR2. However, embodiments of the present inventive concept are not necessarily limited thereto. For example, in an embodiment the width of the bending area BA in the second direction DR2 may be provided in a shape which gradually decreases from the first non-bending area NBA1 towards the second non-bending area NBA2, and is not necessarily limited to any one embodiment.

As illustrated in FIG. 2B, as one portion of the display panel DP is bent, the circuit board PB electrically bonded to the display panel DP may be disposed on the rear surface of the display panel DP.

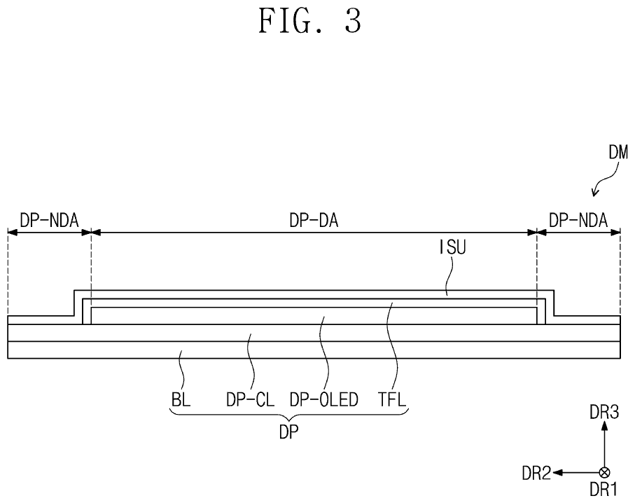

The accommodation member BC may accommodate the display module DM, and be coupled to the window WM. The circuit board PB may be disposed on one end of the display panel DP, and be electrically connected to a circuit element layer DP-CL to be described with reference to FIG. 3. For example, as shown in FIG. 2A, the circuit board PB may be disposed on a lower end of the display panel DP in the first direction DR1. In an embodiment, the display device DD may further include a main board, and electronic modules, a camera module, a power module, and the like that are mounted on the main board.

Although the mobile phone terminal is described above as an example of the display device DD, the display device DD may be various other electronic devices that include two or more bonded electronic components. For example, in an embodiment the display panel DP and the driving chip DC mounted on the display panel DP may correspond to different electronic components from each other, and only these components may constitute the display device DD. The display panel DP and the circuit board PB connected to the display panel DP may also correspond to different electronic components from each other, and only these components may constitute the display device DD. Alternatively, only the main board and the electronic module mounted on the main board may constitute the display device DD. Hereinafter, the display device DD according to an embodiment of the present inventive concept will be described mainly in terms of a bonding structure of the display panel DP and the driving chip DC mounted on the display panel DP.

FIG. 3 is a cross-sectional view of a display module DM according to an embodiment of the present inventive concept.

Referring to FIG. 3, in an embodiment a display panel DP may include a base layer BL, a circuit element layer DP-CL, a display element layer DP-OLED, and an upper insulation layer TFL. An input sensor ISU may be disposed on (e.g., disposed directly thereon) the upper insulation layer TFL.

The display panel DP may include a display area DP-AA and a non-display area DP-NDA. In an embodiment, the display area DP-AA of the display panel DP may correspond to the display area DD-DA illustrated in FIG. 1 or the transmission area TA illustrated in FIG. 2A, and the non-display area DP-NDA may correspond to the non-display area DD-NDA illustrated in FIG. 1 or the non-transmission area NTA illustrated in FIG. 2A.

The base layer BL may include at least one plastic film. In an embodiment, the base layer BL may be a flexible substrate and include a plastic substrate, a glass substrate, a metal substrate, an organic/inorganic composite material substrate, or the like.

The circuit element layer DP-CL may include at least one intermediate insulation layer and a circuit element. In an embodiment, the intermediate insulation layer may include at least one intermediate inorganic layer and at least one intermediate organic layer. The circuit element may include signal lines, a driving circuit of a pixel, and the like. In an embodiment, the insulation layer, a semiconductor layer, and a conductive layer are formed through a process such as coating or deposition. Thereafter, the insulation layer, the semiconductor layer, and the conductive layer may be selectively patterned through a photolithography process and an etching process. A semiconductor pattern, a conductive pattern, the signal lines, and the like are formed through these processes. The patterns disposed on the same layer are formed through the same process. Hereinafter, patterns being formed through the same process means that the patterns include the same material and have the same stacked structure.

The display element layer DP-OLED may include a plurality of light emitting elements. In an embodiment, the display element layer DP-OLED may further include an organic layer such as a pixel defining film.

The upper insulation layer TFL may seal the display element layer DP-OLED. The upper insulation layer TFL may be disposed on (e.g., disposed directly thereon) the display element layer DP-OLED. The upper insulation layer TFL may overlap the display area DP-AA and the non-display area DP-NDA. The upper insulation layer TFL may overlap at least a portion of the non-display area DP-NDA. As an example, the upper insulation layer TFL may include a thin-film encapsulation layer. In an embodiment, the thin-film encapsulation layer may include a stacked structure of inorganic layer/organic layer/inorganic layer. The upper insulation layer TFL may protect the display element layer DP-OLED from moisture, oxygen, and foreign matters such as dust particles. However, embodiments of the present inventive concept are not necessarily limited thereto, and the upper insulation layer TFL may further include an additional insulation layer in addition to the thin-film encapsulation layer. For example, an optical insulation layer for controlling a refractive index may be further included.

In an embodiment of the present inventive concept, an encapsulation substrate may be provided instead of the upper insulation layer TFL. In this embodiment, the encapsulation substrate may oppose the base layer BL, and the circuit element layer DP-CL and the display element layer DP-OLED may be disposed between the encapsulation substrate and the base layer BL (e.g., in the third direction DR3).

In an embodiment, the input sensor ISU may be disposed directly on the display panel DP. A “component A being disposed directly on a component B” herein means that a separate layer (e.g., an intervening layer) is not disposed between the component A and the component B. In this embodiment, the input sensor ISU may be manufactured through a continuous process together with the display panel DP. However, embodiments of the present inventive concept are not necessarily limited thereto, and the input sensor ISU may be provided as an individual panel to be coupled to the display panel DP through an adhesive layer. Alternatively, as an example, the input sensor ISU may be omitted.

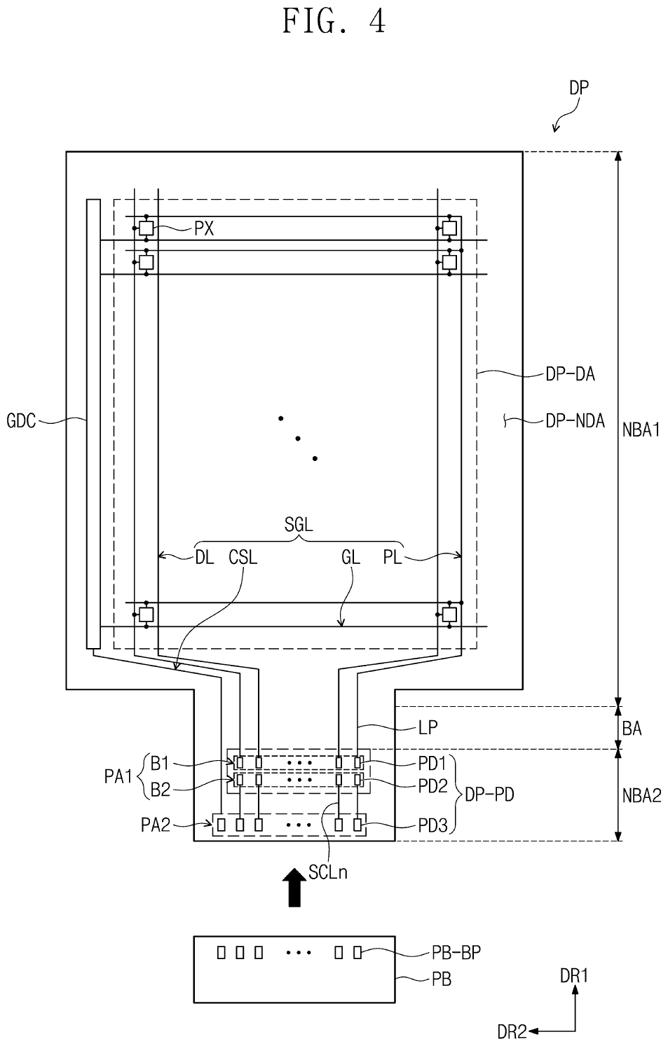

FIG. 4 is a plan view of a display panel DP according to an embodiment of the present inventive concept.

Referring to FIG. 4, in an embodiment the display panel DP may include a plurality of pixels PX, a gate driving circuit GDC, a plurality of signal lines SGL, and a plurality of signal pads DP-PD.

The pixels PX may be disposed on a display area DP-AA. Each of the pixels PX includes a light emitting element and a pixel driving circuit connected to the light emitting element. In an embodiment, the light emitting element may be an organic light emitting element. However, embodiments of the present inventive concept are not necessarily limited thereto. The gate driving circuit GDC sequentially outputs gate signals to a plurality of gate lines GL to be described later. In an embodiment, a transistor of the gate driving circuit GDC may be formed through the same process as a transistor of the pixel PX, for example, a low temperature polycrystalline silicon (LTPS) process or a low temperature polycrystalline oxide (LTPO) process. The display panel DP may further include another driving circuit that provides the pixels PX with an emission control signal.

In an embodiment, the signal lines SGL may include the gate lines GL, data lines DL, a power line PL, and a control signal line CSL. Each of the gate lines GL may be connected to a corresponding pixel PX of the pixels PX, and each of the data lines DL may be connected to a corresponding pixel PX of the pixels PX. The power line PL may be connected to the pixels PX. The control signal line CSL may provide a scan driving circuit with the control signals.

The signal lines SGL may overlap the display area DP-AA and the non-display area DP-NDA (e.g., in the third direction DR3). Each of the signal lines SGL may include a line portion LP. In an embodiment, each of the signal lines SGL may further include a pad portion. The line portion LP may overlap the display area DP-AA and the non-display area DP-NDA (e.g., in the third direction DR3). The pad portion may be connected to a distal end of the line portion LP.

In an embodiment, the plurality of signal pads DP-PD may include first pads PD1, second pads PD2, and third pads PD3. An area in which the first and second pads PD1 and PD2 are disposed may be defined as a first pad area PA1, and an area in which the third pads PD3 are disposed may be defined as a second pad area PA2.

The first pad area PA1 may be an area overlapping the driving chip DC in FIG. 2A, and the second pad area PA2 may be an area overlapping the circuit board PB. In an embodiment, the first pad area PA1 may include a first area B1 in which the first pads PD1 are disposed, and a second area B2 in which the second pads PD2 are disposed. The first pad area PA1 and the second pad area PA2 may be disposed within the non-display area DP-NDA. The first pad area PA1 and the second pad area PA2 may be spaced apart from each other in the first direction DR1. Although an example in which one pad row is disposed in the first pad area PA1 is illustrated, embodiments of the present inventive concept are not necessarily limited thereto, and a plurality of pad rows may be disposed in the first pad area PA1.

In an embodiment, each of the first pads PD1 may be connected to a corresponding data line of the data lines DL. The first pads PD1 and the second pads PD2 may be electrically connected to each other. The second pads PD2 may be connected to the third pads PD3 through connection signal lines SCLn, respectively.

The circuit board PB may include a plurality of board bump electrodes PB-BP. In an embodiment, the plurality of board bump electrodes PB-BP may be arranged in the second direction DR2. In an embodiment, the board bump electrodes PB-BP of the circuit board PB may be in direct contact with the third pads PD3 of the second pad area PA2 to be electrically connected to the third pads PD3.

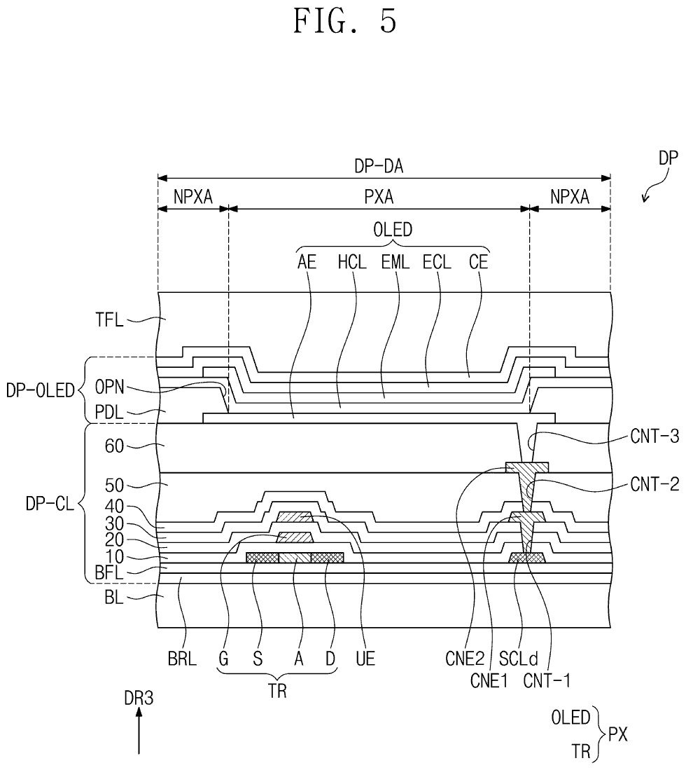

FIG. 5 is a cross-sectional view of a display panel DP illustrating a pixel PX according to an embodiment of the present inventive concept.

Referring to FIG. 5, a display area DP-AA may include an emissive area PXA and a non-emissive area NPXA. Each of the pixels PX may include a light emitting element OLED and a pixel driving circuit connected to the light emitting element OLED. For example, the pixel PX may include a transistor TR and the light emitting element OLED.

As an example, one transistor TR is illustrated in FIG. 5. However, embodiments of the present inventive concept are not necessarily limited thereto. In an embodiment, the pixel PX according to an embodiment may include seven transistors and at least one capacitor, and the seven transistors and the capacitor may be electrically connected to each other. However, the number of each of the transistor and the capacitor, which constitute the pixel PX, is not necessarily limited to any one embodiment and may vary.

In an embodiment, the display panel DP may include a plurality of insulation layers, a semiconductor pattern, a conductive pattern, a signal line, and the like. The insulation layers, a semiconductor layer, and a conductive layer may be formed through a method such as coating or deposition. Thereafter, the insulation layers, the semiconductor layer, and the conductive layer may be selectively patterned through photolithography. The semiconductor pattern, the conductive pattern, and the signal line, and the like, which are included in a circuit element layer DP-CL and a display element layer DP-OLED, may be formed through those methods.

A base layer BL may include a synthetic resin film. The base layer BL may have a multilayer structure. For example, in an embodiment the base layer BL may have a three-layer structure of a synthetic resin layer, an inorganic layer and a synthetic resin layer. For example, the synthetic resin layer may be a polyimide-based resin layer, and a material thereof is not particularly limited. In addition, the base layer BL may include a glass substrate, a metal substrate, an organic/inorganic composite material substrate, or the like.

In an embodiment, the circuit element layer DP-CL may include a barrier layer BRL, a buffer layer BFL, first to sixth insulation layers 10 to 60, the transistor TR, a connection signal line SCLd, an upper electrode UE, a first connection electrode CNE1, and a second connection electrode CNE2.

At least one inorganic layer is disposed on (e.g., disposed directly thereon) a top surface of the base layer BL. The inorganic layer may be provided in a multilayer structure. The barrier layer BRL may be disposed on the base layer BL (e.g., disposed directly thereon in the third direction DR3). The buffer layer BFL may be disposed on the barrier layer BRL (e.g., disposed directly thereon in the third direction DR3). The barrier layer BRL and the buffer layer BFL may be inorganic layers.

A semiconductor pattern is disposed on the buffer layer BFL (e.g., disposed directly thereon in the third direction DR3). In an embodiment, the semiconductor pattern may include polysilicon. However, embodiments of the present inventive concept are not necessarily limited thereto. For example, in an embodiment the semiconductor pattern may include amorphous silicon or a metal oxide.

FIG. 5 just illustrates a portion of the semiconductor pattern, and the semiconductor pattern may be further disposed in another area of the pixel PX on a plane. For example, the semiconductor pattern may be arranged over the pixels according to a specific rule. The semiconductor pattern may have different electrical properties according to whether or not the semiconductor pattern is doped. The semiconductor pattern may include a first region and a second region. The first region may be doped with an n-type dopant or a p-type dopant. A p-type transistor includes a doped region doped with the p-type dopant.

The first region may have higher conductivity than the second region, and substantially serve as an electrode or a signal line. The second region may be a region that has a low doping concentration or is not doped, and may substantially correspond to an active (e.g., a channel) of a transistor. For example, one portion of the semiconductor pattern may be an active of the transistor, another portion thereof may be a source or a drain of the transistor, and still another portion thereof may be a connection electrode or a connection signal line.

As illustrated in FIG. 5, a source S, an active A, and a drain D of the transistor TR may be provided from the semiconductor pattern.

FIG. 5 illustrates one portion of the connection signal line SCLd provided from the semiconductor pattern. In an embodiment, the connection signal line SCLd may be electrically connected to a drain of one of the transistors in the pixel PX.

The first insulation layer 10 is disposed on the buffer layer BFL (e.g., disposed directly thereon in the third direction DR3). The first insulation layer 10 may cover the semiconductor pattern. In an embodiment, the first insulation layer 10 may overlap the plurality of pixels in common. The gate G may be disposed on the first insulation layer 10 (e.g., disposed directly thereon in the third direction DR3). In an embodiment, the gate G may be a portion of a metal pattern. The gate G may overlap the active A (e.g., in the third direction DR3). In an embodiment, the gate G may function as a mask in a process of doping the semiconductor pattern.

The second insulation layer 20 that covers the gate G may be disposed on the first insulation layer 10 (e.g., disposed directly thereon in the third direction DR3). In an embodiment, the second insulation layer 20 may overlap the pixels in common. The upper electrode UE may be disposed on the second insulation layer 20 (e.g., disposed directly thereon in the third direction DR3). The upper electrode UE may overlap the gate G of the transistor TR (e.g., in the third direction DR3). In an embodiment, the upper electrode UE may be one portion of a metal pattern. In an embodiment, a portion of the gate G and the upper electrode UE overlapping the one portion may define a capacitor.

The third insulation layer 30 that covers the upper electrode UE may be disposed on the second insulation layer 20 (e.g., disposed directly thereon in the third direction DR3). In an embodiment, the first connection electrode CNE1 disposed on the third insulation layer 30 may be connected to (e.g., directly connected thereto) the connection signal line SCLd through a contact hole CNT-1 passing through the first to third insulation layers 10 to 30.

The fourth insulation layer 40 that covers the first connection electrode CNE1 may be disposed on the third insulation layer 30 (e.g., disposed directly thereon in the third direction DR3). The first to fourth insulation layers 10 to 40 may be inorganic layers and/or organic layers, and may have a single-layer or multilayer structure.

In an embodiment, the first connection electrode CNE1 may be disposed on the fourth insulation layer 40, and be covered by the fifth insulation layer 50. Alternatively, an embodiment may include all of a first connection electrode, which is disposed on the third insulation layer 30 and covered by the fourth insulation layer 40, and a first connection electrode which is disposed on the fourth insulation layer 40 and covered by the fifth insulation layer 50.

The fifth insulation layer 50 may be disposed on the fourth insulation layer 40 (e.g., disposed directly thereon in the third direction DR3). The fifth insulation layer 50 may be an organic layer. The second connection electrode CNE2 may be disposed on the fifth insulation layer 50 (e.g., disposed directly thereon in the third direction DR3). In an embodiment, the second connection electrode CNE2 may be connected to (e.g., directly connected thereto) the first connection electrode CNE1 through a contact hole CNT-2 passing through the fourth insulation layer 40 and the fifth insulation layer 50.

The sixth insulation layer 60 that covers the second connection electrode CNE2 may be disposed on the fifth insulation layer 50 (e.g., disposed directly thereon in the third direction DR3). The sixth insulation layer 60 may be an organic layer. A first electrode AE may be disposed on the sixth insulation layer 60 (e.g., disposed directly thereon in the third direction DR3). In an embodiment, the first electrode AE may be connected to (e.g., directly connected thereto) the second connection electrode CNE2 through a contact hole CNT-3 passing through the sixth insulation layer 60.

The circuit element layer DP-CL may include a plurality of connection electrodes connected to the transistors, and some of the plurality of connection electrodes may be disposed on different layers from each other. In an embodiment, the first connection electrode CNE1 may extend to be connected to the transistor TR. However, positions of the plurality of connection electrodes are not necessarily limited to any one embodiment.

The display element layer DP-OLED may include a pixel defining film PDL and the light emitting element OLED. A pixel opening portion OPN may be defined in the pixel defining film PDL. The pixel opening portion OPN of the pixel defining film PDL may expose at least one portion of the first electrode AE, such as a central portion of the first electrode AE. In this embodiment, the emissive area PXA may be defined to correspond to a partial area of the first electrode AE, which is exposed by the pixel opening portion OPN.

In an embodiment, a hole control layer HCL may be disposed, in common, in the emissive area PXA and the non-emissive area NPXA. The hole control layer HCL may include a hole transport layer and/or a hole injection layer. An emissive layer EML may be disposed on the hole control layer HCL (e.g., disposed directly thereon in the third direction DR3). In an embodiment, the emissive layer EML may be disposed in an area corresponding to the pixel opening portion OPN. For example, the emissive layer EML may be separately provided in each of the pixels. However, embodiments of the present inventive concept are not necessarily limited thereto, and the emissive layer EML may be provided in the plurality of pixels PX in common by using an open mask.

In an embodiment, an electron control layer ECL may be disposed on the emissive layer EML (e.g., disposed directly thereon in the third direction DR3). The electron control layer ECL may include an electron transport layer and/or an electron injection layer. The hole control layer HCL and the electron control layer ECL may be provided in the pixels in common by using an open mask. A second electrode CE may be disposed on the electron control layer ECL (e.g., disposed directly thereon in the third direction DR3). The second electrode CE may have a shape of one body and be disposed in the pixels in common. An upper insulation layer TFL may be disposed on the second electrode CE (e.g., disposed directly thereon in the third direction DR3). The upper insulation layer TFL may include a plurality of thin films.

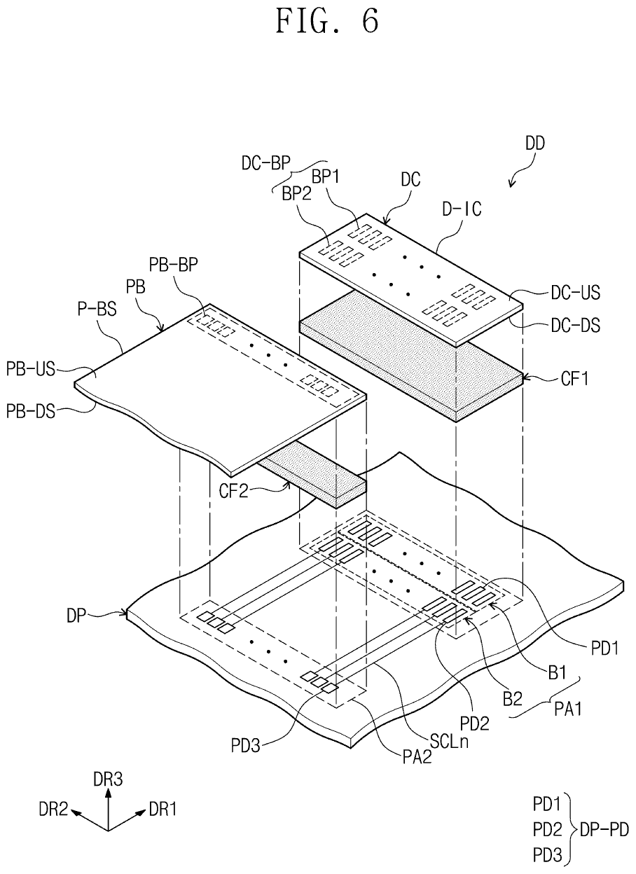

FIG. 6 is an enlarged exploded perspective view of pad areas PA1 and PA2 of a display device DD according to an embodiment of the present inventive concept. As an example, FIG. 6 illustrates a driving chip DC and a circuit board PB as being separated from a display panel DP. First pads PD1, second pads PD2, connection signal lines SCLn, and third pads PD3 in FIG. 6 are the same as the first pads PD1, the second pads PD2, the connection signal lines SCLn, and the third pads PD3 in FIG. 4, respectively, and thus will not be described or will be briefly described.

Referring to FIGS. 4 and 6, in an embodiment the driving chip DC may be bonded to a first pad area PA1 through a first adhesive layer CF1. The circuit board PB may be bonded to a second pad area PA2 through a second adhesive layer CF2. In an embodiment, the first and second adhesive layers CF1 and CF2 may each include a synthetic resin having an adhesive property. Each of the first and second adhesive layers CF1 and CF2 may be a non-conductive film. For example, each of the first and second adhesive layers CF1 and CF2 may include only the synthetic resin having an adhesive property without including a conductive ball.

The driving chip DC may include a driving integrated circuit D-IC and chip bump electrodes DC-BP mounted in the driving chip DC. The driving integrated circuit D-IC may include a top surface DC-US and a bottom surface DC-DS opposing the top surface DC-US (e.g., in the third direction DR3), and the bottom surface DC-DS may be a surface facing the first and second pads PD1 and PD2. The chip bump electrodes DC-BP may be disposed on the bottom surface DC-DS of the driving integrated circuit D-IC.

In an embodiment, the chip bump electrodes DC-BP may include first bumps BP1 electrically connected to the first pads PD1, respectively, and second bumps BP2 electrically connected to the second pads PD2, respectively. In an embodiment, the first bumps BP1 may be arranged in the second direction DR2, and the second bumps BP2 may be spaced apart from the first bumps BP1 in the first direction DR1 and arranged in the second direction DR2.

In an embodiment, the driving chip DC may receive first signals from the outside (e.g., an external device) through the second pads PD2 and the second bumps BP2. The driving chip DC may provide second signals generated based on the first signals to the first pads PD1 through the first bumps BP1. For example, the driving chip DC may include a data driving circuit. The first signals may be image signals that are digital signals applied from the outside (e.g., an external device), and the second signals may be data signals that are analog signals. In an embodiment, the driving chip DC may generate analog voltages corresponding to grayscale values of the image signals. The data signals may be provided to the pixel PX through the data line DL illustrated in FIG. 4.

In an embodiment, each of the first bumps BP1 and the second bumps BP2 may have a shape that protrudes from the bottom surface DC-DS of the driving integrated circuit D-IC to be exposed to the outside (e.g., the external environment). When the first adhesive layer CF1 is cured, the first pads PD1 and the first bumps BP1 may be fixed in a contact state, and the second pads PD2 and the second bumps BP2 may be fixed in a contact state.

In an embodiment, the circuit board PB may include a base layer P-BS and board bump electrodes PB-BP mounted in the circuit board PB. The circuit board PB may include a top surface PB-US and a bottom surface PB-DS, and the bottom surface PB-DS may be a surface facing the third pads PD3 (e.g., in the third direction DR3). The board bump electrodes PB-BP may be disposed on the bottom surface PB-DS of the base layer P-BS. The board bump electrodes PB-BP may be electrically connected to the third pads PD3, respectively. The board bump electrodes PB-BP may be arranged in the second direction DR2. The circuit board PB may provide the driving chip DC with image signals, driving voltages, and other control signals.

In an embodiment, the board bump electrodes PB-BP may have a shape that protrudes from the bottom surface PB-DS of the base layer P-BS to be exposed to the outside (e.g., the external environment). When the second adhesive layer CF2 is cured, the third pads PD3 and the board bump electrodes PB-BP may be fixed in a contact state.

An electronic component may include a substrate and a bump electrode disposed below the substrate. In an embodiment in which the electronic component corresponds to the driving chip DC, the substrate may correspond to the driving integrated circuit D-IC of the driving chip DC, and the bump electrode may correspond to the chip bump electrode DC-BP. Alternatively, in an embodiment in which the electronic component corresponds to the circuit board PB, the substrate may correspond to the base layer P-BS of the circuit board PB, and the bump electrode may correspond to the board bump electrode PB-BP.

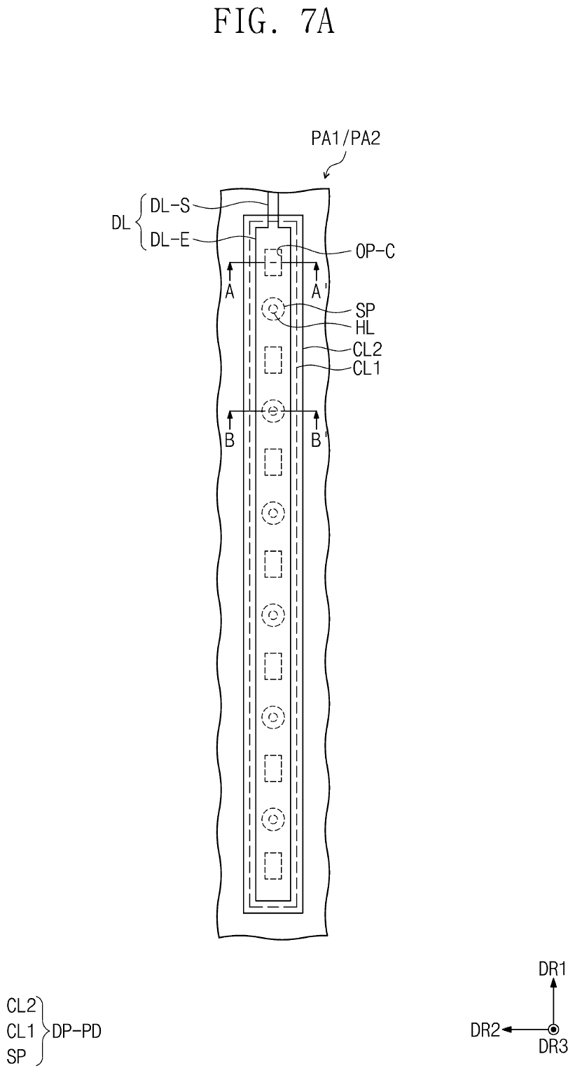

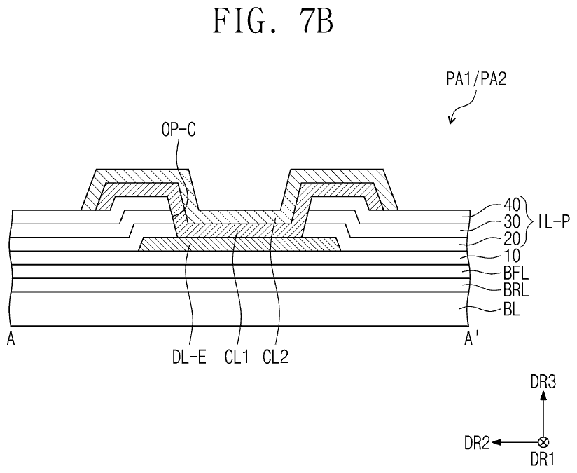

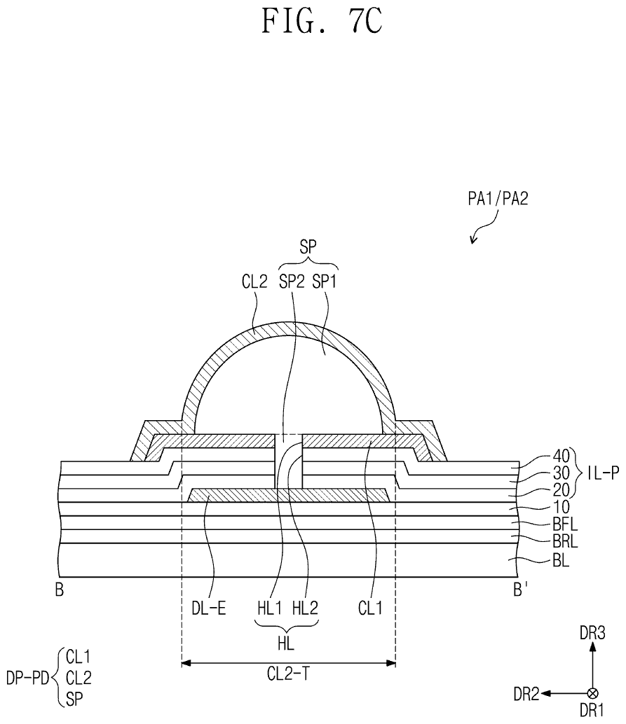

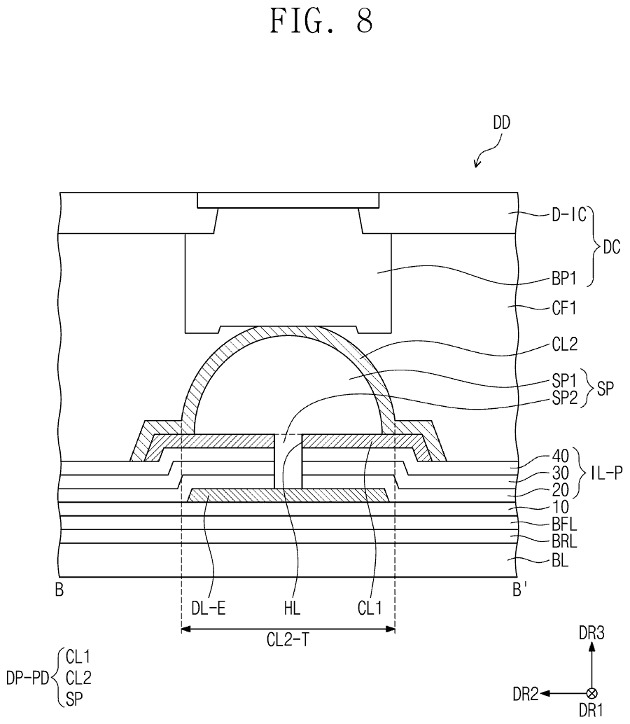

FIG. 7A is a schematic plan view of pad areas PA1 and PA2 according to an embodiment of the present inventive concept. FIGS. 7B and 7C are each a cross-sectional view of the pad areas PA1 and PA2 according to embodiments of the present inventive concept. FIG. 7B is a cross-sectional view of the pad areas PA1 and PA2 corresponding to line A-A′ in FIG. 7A, and FIG. 7C is a cross-sectional view of the pad areas PA1 and PA2 corresponding to line B-B′ in FIG. 7A. FIG. 8 is a cross-sectional view illustrating a bonding structure of a display device DD according to an embodiment of the present inventive concept.

A signal pad DP-PD (e.g., a signal pad structure) illustrated in FIGS. 7A to 8 may be any one of the first to third pads PD1 to PD3 described with reference to FIGS. 4 and 6. FIG. 7A illustrates, as an example of a signal line, a data line DL including an end portion DL-E and a line portion DL-S that have different widths from each other. However, embodiments of the present inventive concept are not necessarily limited thereto. Here, the width may mean a length or width of the end portion DL-E or the line portion DL-S in the second direction DR2. The signal line may be a signal line other than the data line DL, and may have a uniform width regardless of the end portion DL-E and the line portion DL-S. The end portion DL-E may correspond to the pad portion described above with reference to FIG. 4.

Hereinafter, the pad areas PA1 and PA2 will be described mainly in terms of a first pad area PA1 in which the data line DL is disposed. The same description of the first pad area PA1 may apply to a second pad area PA2 except that the connection signal line SCLn (see FIG. 4) is disposed instead of the data line DL.

Referring to FIG. 7A, in an embodiment the signal pad DP-PD may include a first conductive pattern CL1, a second conductive pattern CL2, and at least one insulation pattern SP. In an embodiment, the first conductive pattern CL1 may be connected to the end portion DL-E of the data line DL through at least one contact hole OP-C. As an example, an embodiment shown in FIG. 7A illustrates the signal pad DP-PD including seven contact holes OP-C and six insulation patterns SP. However, the number of the contact holes OP-C and the number of the insulation patterns SP are not necessarily limited thereto.

The end portion DL-E may have a shape extending longitudinally in the first direction DR1 on a plane. For example, in the end portion DL-E, a length or width in the first direction DR1 may be greater than a length or width in the second direction DR2.

The contact holes OP-C may overlap the end portion DL-E on a plane. In an embodiment, the contact holes OP-C may be arranged in the first direction DR1. For example, each of the contact holes OP-C may be disposed to be spaced apart from each other in the first direction DR1. One portion of the first conductive pattern CL1 may overlap the contact holes OP-C on a plane.

The insulation patterns SP may overlap the second conductive pattern CL2 on a plane. The insulation patterns SP may be disposed to be spaced apart from the contact holes OP-C on a plane. For example, the insulation patterns SP may be spaced apart from the contact holes OP-C in the first direction DR1. In an embodiment, the insulation patterns SP may be arranged in the first direction DR1. For example, the insulation patterns SP may be disposed to be spaced apart from each other in the first direction DR1.

In an embodiment, each of the insulation patterns SP may be disposed between the contact holes OP-C adjacent thereto. As an example, FIG. 7A illustrates the six insulation patterns SP that are disposed, respectively, in six planes between the seven contact holes OP-C. However, an arrangement relationship of the insulation patterns SP with respect to the contact hole OP-C is not necessarily limited thereto.

As an example, FIG. 7A illustrates the insulation patterns SP each having a circular shape on a plane. However, embodiments of the present inventive concept are not necessarily limited thereto. The shapes of the insulation patterns SP on a plane may be changed to polygon shapes, oval shapes, or the like. In addition, the shapes of the insulation patterns SP are not limited to shapes that are the same as each other. For example, one or more insulation patterns SP may have different shapes from each other (e.g., in a plan view).

Referring to FIGS. 7B and 7C, the end portion DL-E may be disposed on a first insulation layer 10 (e.g., disposed directly thereon in the third direction DR3). The end portion DL-E may be disposed on the same layer as the gate G illustrated in FIG. 5. In an embodiment, the end portion DL-E may be formed through the same process as the gate G. The end portion DL-E may include the same material as the gate G.

However, embodiments of the present inventive concept are not necessarily limited thereto and the position of the end portion DL-E may vary. For example, in an embodiment the end portion DL-E may be disposed on the same layer, include the same material, and have the same stacked structure as the upper electrode UE illustrated in FIG. 5. Alternatively, in an embodiment some of the plurality of signal lines may be formed through the same process as the gate G (see FIG. 5), and others may be formed through the same process as the upper electrode UE (see FIG. 5).

In an embodiment, the data line DL may be disposed on one layer to have a shape of one body. However, embodiments of the present inventive concept are not necessarily limited thereto. For example, in an embodiment one data line DL may include a plurality of portions disposed on different layers from each other. For example, the line portion DL-S may include two or more portions.

The first conductive pattern CL1 may be disposed on a fourth insulation layer 40 (e.g., disposed directly thereon in the third direction DR3). The first conductive pattern CL1 may be connected to (e.g., directly connected thereto) the end portion DL-E through the contact hole OP-C passing through second to fourth insulation layers 20, 30 and 40. For example, the first conductive pattern CL1 may be in direct contact with the end portion DL-E through the contact hole OP-C. In an embodiment, the second to fourth insulation layers 20, 30 and 40 may be formed the same process as the second to fourth insulation layers 20, 30 and 40 of the display area DP-AA illustrated in FIG. 5. In the present specification, insulation layers disposed between the end portion DL-E and the first conductive pattern CL1 (e.g., in the third direction DR3) may be defined as a pad insulation layer IL-P. For example, in an embodiment shown in FIG. 7B, the second to fourth insulation layers 20, 30 and 40 may be defined as the pad insulation layer IL-P. However, embodiments of the present inventive concept are not necessarily limited thereto and the stacked structure of the pad insulation layer IL-P may be changed according to the stacked structure of the circuit element layer DP-CL (see FIG. 5). For example, in an embodiment, the contact hole OP-C may be defined by additional insulation layers other than the second to fourth insulation layers 20, 30 and 40, or may be defined by fewer insulation layers than the second to fourth insulation layers 20, 30 and 40.

The first conductive pattern CL1 and the end portion DL-E may be distinguished by the pad insulation layer IL-P (e.g., the second to fourth insulation layers 20, 30 and 40) disposed therebetween.

The second conductive pattern CL2 may be disposed on (e.g., disposed directly thereon) the first conductive pattern CL1. An area (e.g., a first portion) of the second conductive pattern CL2, which does not overlap the insulation pattern SP (e.g., on the plane), may be in direct contact with a first portion of the first conductive pattern CL1. An area (e.g., a second portion) of the second conductive pattern CL2, which overlaps the insulation pattern SP, of the second conductive pattern CL2 may be in direct contact with the insulation pattern SP and may be spaced apart from a second portion of the first conductive pattern CL1 by the insulation pattern SP which overlaps the second portion of the first conductive pattern CL1 on a plane.

In an embodiment, the first conductive pattern CL1 may be formed through the same process as the first connection electrode CNE1 described above with reference with FIG. 5, and the second conductive pattern CL2 may be formed through the same process as the second connection electrode CNE2 described above with reference with FIG. 5. The first conductive pattern CL1 may include the same material as the first connection electrode CNE1 (see FIG. 5), and the second conductive pattern CL2 may include the same material as the second connection electrode CNE2 (see FIG. 5). As an example, FIGS. 7B and 7C each illustrate an embodiment in which the first conductive pattern CL1 is disposed on (e.g., disposed directly thereon) the fourth insulation layer 40. However, embodiments of the present inventive concept are not necessarily limited thereto. For example, in an embodiment, the first conductive pattern CL1 may be disposed on (e.g., disposed directly thereon) the third insulation layer 30, and in this embodiment, the fourth insulation layer 40 may not be disposed in the pad areas PA1 and PA2. However, embodiments of the present inventive concept are not necessarily limited thereto, and a combination of the connection electrodes formed through the same process as the first and second conductive patterns CL1 and CL2 may be variously selected according to the stacked structure of the circuit element layer DP-CL (see FIG. 5) as long as it is capable of providing the first and second conductive patterns CL1 and CL2 on different layers from each other.

An example, an embodiment in which the second conductive pattern CL2 has a larger surface area than the first conductive pattern CL1, and the second conductive pattern CL2 has an edge disposed outside an edge of the first conductive pattern CL1 and covers the edge of the first conductive pattern CL1 on a plane, is illustrated in FIGS. 7B and 7C. However, embodiments of the present inventive concept are not necessarily limited thereto. For example, in an embodiment the second conductive pattern CL2 may have substantially the same surface area as the first conductive pattern CL1 (e.g., in a plan view), and the edge of the second conductive pattern CL2 may be substantially aligned with the edge of the first conductive pattern CL1.

One portion of the second conductive pattern CL2 may include a portion overlapping the insulation pattern SP on a plane. The insulation pattern SP may be disposed between the first conductive pattern CL1 and the second conductive pattern CL2 in a cross-sectional view (e.g., in the third direction DR3). The insulation pattern SP may be disposed on (e.g., disposed directly thereon) the first conductive pattern CL1 and may be covered by the second conductive pattern CL2. The second conductive pattern CL2 may cover a top surface of the insulation pattern SP. The insulation pattern SP may be disposed inside each of the first conductive pattern CL1 and the second conductive pattern CL2 on a plane. For example, an entirety of the insulation pattern SP may be disposed inside each of the first conductive pattern CL1 and the second conductive pattern CL2 on a plane.

In an embodiment, the second conductive pattern CL2 may have a multilayer structure. For example, in an embodiment the second conductive pattern CL2 may have a three-layer structure in which a first layer, a second layer, and a third layer are sequentially stacked (e.g., in the third direction DR3). The second layer may have higher conductivity than each of the first layer and the third layer. For example, in an embodiment the first layer and the third layer may be titanium (Ti), and the second layer may be aluminum (Al).

A through-hole HL1 may be defined in the first conductive pattern CL1. A through-hole HL2 may be also defined in the pad insulation layer IL-P. The through-hole HL1 passing through the first conductive pattern CL1 may be referred to as a first through-hole, and the through-hole HL2 passing through the pad insulation layer IL-P may be referred to as a second through-hole.

In an embodiment in which the through-hole HL1 is defined only in the first conductive pattern CL1, and the through-hole HL2 is not defined in the pad insulation layer IL-P, the through-hole HL may only include the first through-hole HL1. In an embodiment in which the through-holes HL1 and HL2 are defined in the first conductive pattern CL1 and the pad insulation layer IL-P, respectively, the through-hole HL may include both the first through-hole HL1 and the second through-hole HL2.

The second through-hole HL2 may extend from (e.g., extend directly therefrom) the first through-hole HL1 to be provided as one body with the first through-hole HL1. FIG. 7C illustrates an embodiment in which the second through-hole HL2 are defined in all of the second to fourth insulation layers 20, 30 and 40 included in the pad insulation layer IL-P. However, embodiments of the present inventive concept are not necessarily limited thereto. For example, in some embodiments the second through-hole HL2 may be defined only in the fourth insulation layer 40, or may be defined only in the third and fourth insulation layers 30 and 40.

The through-hole HL may be defined in a portion overlapping the insulation pattern SP on a plane. The through-hole HL may be filled by one portion of the insulation pattern SP. For example, in an embodiment the insulation pattern SP may extend into the first through-hole HL1 and the second through-hole HL2. In an embodiment in which the insulation pattern SP is disposed on the first conductive pattern CL1 while filling the through-hole HL, a contact area between the insulation pattern SP and layers (e.g., the first conductive pattern CL1 and the pad insulation layer IL-P) disposed below the insulation pattern SP may be increased compared to a comparative embodiment in which the insulation pattern SP is disposed on the first conductive pattern CL1 without the through-hole HL. Accordingly, the insulation pattern SP may be fixed without being lost from the layers disposed below the insulation pattern SP.

A top surface of the insulation pattern SP may be defined as a surface on which the insulation pattern SP is in direct contact with the second conductive pattern CL2. A bottom surface of the insulation pattern SP may be defined as all surfaces of the insulation pattern SP except the top surface of the insulation pattern SP. The bottom surface of the insulation pattern SP may include a surface in direct contact with a top surface of the first conductive pattern CL1, and a surface surrounding the portion filled inside the through-hole HL.

In an embodiment, the insulation pattern SP may include a first portion SP1 and a second portion SP2. The first portion SP1 may be a portion disposed between the first conductive pattern CL1 and the second conductive pattern CL2 (e.g., in the third direction DR3). For example, in an embodiment shown in FIG. 7C, the first portion SP1 may be a portion that has a semicircular shape in a cross-sectional view. The second portion SP2 may mean a portion that protrudes from the first portion SP1 in a direction away from an upper surface of the second conductive pattern CL2 and towards a base layer BL. The second portion SP2 may be referred to as a protrusion. The second portion SP2 may be a portion that fills the through-hole HL. In an embodiment, the first portion SP1 and the second portion SP2 may have a shape of one body and may be integral with each other.

The insulation pattern SP may have a shape in which a semicircular shape and a protrusion shape protruding from the semicircular shape are combined in a cross-sectional view. The semicircular shape may be a shape of a semicircle in a cross-sectional view in which the top surface of the insulation pattern SP is round. The protrusion shape may be a shape protruding from a surface, which is not round, of the semicircular shape. However, embodiments of the present inventive concept are not necessarily limited thereto, and the insulation pattern SP may have a shape in which a trapezoidal shape, a rectangular shape, or an inverted trapezoidal shape, and a protrusion shape protruding therefrom are combined (e.g., in an integral form with respect to each other) in a cross-sectional view.

The insulation pattern SP may include a polymer. In an embodiment, the insulation pattern SP may include a thermoset polymer. However, embodiments of the present inventive concept are not necessarily limited thereto, and the insulation pattern SP may include a thermoplastic polymer in some embodiments. The first portion SP1 and the second portion SP2 may include the same material as each other, and be formed through the same process.

In an embodiment, the insulation pattern SP may be formed through the same process as the fifth insulation layer 50 (see FIG. 5). However, embodiments of the present inventive concept are not necessarily limited thereto, and a combination of the connection electrodes formed through the same process as the first and second conductive patterns CL1 and CL2 may be variously selected according to the stacked structure of the circuit element layer DP-SP (see FIG. 5). Accordingly, the insulation layer formed through the same process as the insulation pattern SP may also be variously selected.

A portion of the second conductive pattern CL2 which covers the insulation pattern SP may protrude from the first conductive pattern CL1 in the third direction DR3, when compared to the remaining portion of the second conductive pattern CL2. The protruding portion of the second conductive pattern CL2 may be referred to as a protrusion CL2-T. The second conductive pattern CL2 may be in direct contact with each of a top surface of the first conductive pattern CL1 that does not overlap the insulation pattern SP (e.g., in the third direction DR3), and the top surface of the insulation pattern SP. The protrusion CL2-T of the second conductive pattern CL2 may correspond to a portion that is in direct contact with the top surface of the insulation pattern SP.

As an example, FIG. 8 illustrates a driving chip DC as an electronic component. FIG. 8 illustrates a state in which the first bump BP1 of the chip bump electrodes DC-BP (see FIG. 6) of the driving chip DC is in direct contact with the first pad PD1 (see FIG. 6). The first pad PD1 (see FIG. 6) is illustrated as a signal pad DP-PD in FIG. 8.

The first bump BP1 of the driving chip DC may pass through the first adhesive layer CF1 to be in direct contact with the second conductive pattern CL2 of the signal pad DP-PD through a bonding process. As the display device DD according to an embodiment of the present inventive concept does not include a conductive ball, even though the signal pads DP-PD are densely disposed, a short-circuit defect due to the conductive ball and/or an electrical conduction defect of a case in which the conductive ball is not disposed between the signal pad DP-PD and the bump electrode may be prevented. Accordingly, a high-resolution panel may be achieved.

In general, as a height of the insulation pattern SP increases, a risk of the loss of the insulation pattern SP increases. However, the height of the insulation pattern SP may be designed to be relatively large by increasing a fixing force of the insulation pattern SP like an embodiment of the present inventive concept. In an embodiment in which the height of the insulation pattern SP is designed to be relatively large, contact reliability with the bump BP1 may be increased.

Even in a case in which the adhesive layer CF1 is detached from the signal pad DP-PD to reattach the adhesive layer CF1 during the process, as the fixing force of the insulation pattern SP is increased, the pad areas PA1 and PA2 of the display panel DP (see FIG. 6) including the signal pad DP-PD may not be damaged, and thus the display panel DP (see FIG. 6) may be reused.

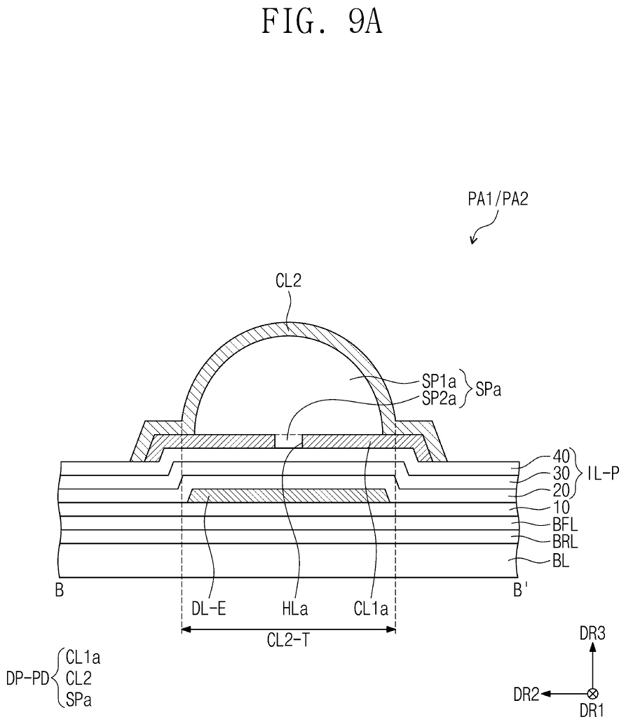

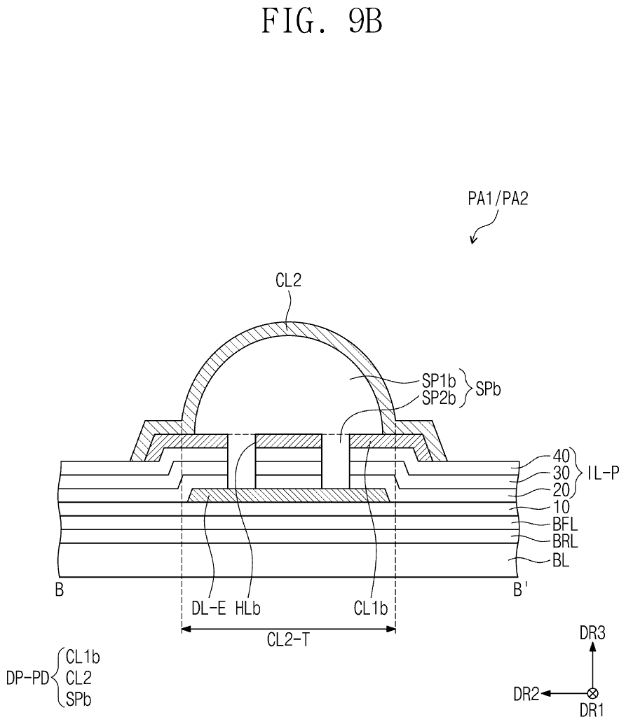

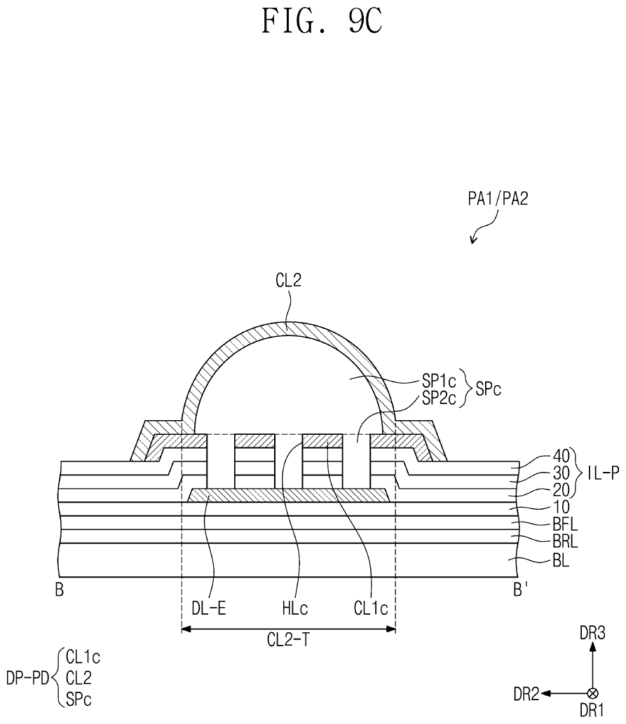

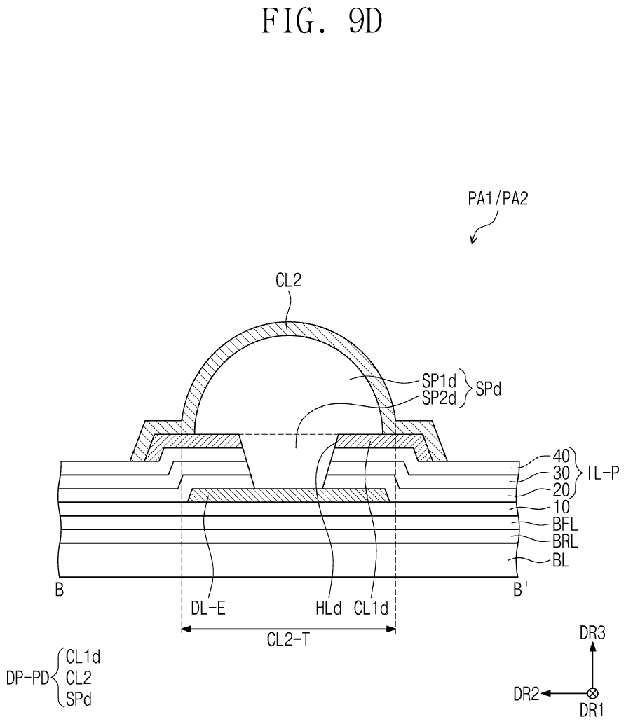

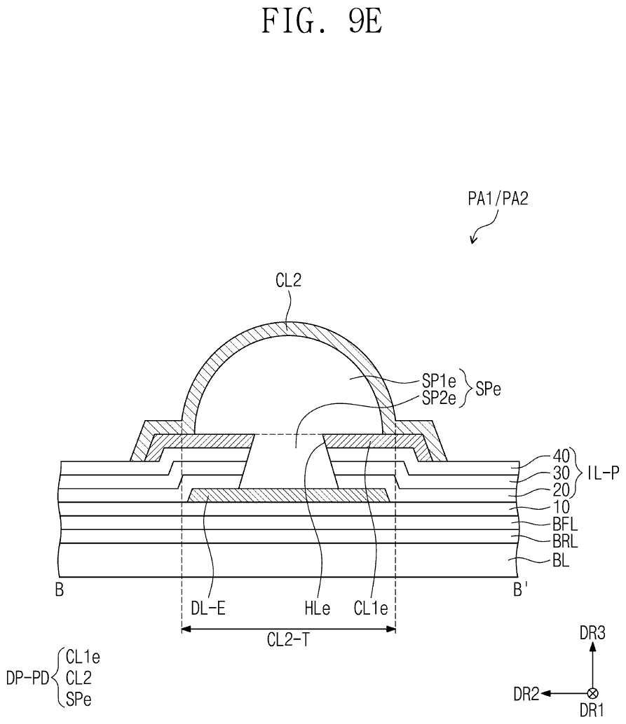

FIGS. 9A to 9E are each a cross-sectional view of pad areas PA1 and PA2 according to embodiments of the present inventive concept. FIGS. 9A to 9E illustrate other examples of the cross-sectional view corresponding to line B-B′ in FIG. 7A, and may be different in terms of the shape of the through-hole HL illustrated in FIG. 7A. Except the matters related to the shape of the through-hole HL, the same contents described above with reference to FIGS. 7A to 8 may apply to FIGS. 9A to 9E and a repeated description of similar or identical elements may be omitted for economy of explanation.

Referring to FIG. 9A, in an embodiment a through-hole HLa may be defined only in a first conductive pattern CL1a, and the through-hole HLa may not be defined in the pad insulation layer IL-P. Accordingly, a first portion SP1a of an insulation pattern SPa may have the same shape as the first portion SP1 in FIG. 7C, but unlike the second portion SP2 in FIG. 7C, a second portion SP2a may be a protrusion that fills only the through-hole HLa defined in the first conductive pattern CL1a.

A shape and/or a surface area of the through-hole HLa in FIG. 9A on a plane may be the same as or may be different from the shape and/or the surface area of the through-hole HL in FIG. 7A, and may not be necessarily limited to any shape and/or surface area.

Referring to FIGS. 9B and 9C, in an embodiment each of through-holes HLb and HLc may be provided in plurality. In an embodiment shown in FIG. 9B, two through-holes HLb may be defined. A first portion SP1b of an insulation pattern SPb may have the same shape as the first portion SP1 in FIG. 7C, and a second portion SP2b may have the same shape as the second portion SP2 in FIG. 7C but may be configured in two protrusions. In an embodiment shown in FIG. 9C, three through-holes HLc may be defined. A first portion SP1c of an insulation pattern SPc may have the same shape as the first portion SP1 in FIG. 7C, and a second portion SP2c may have the same shape as the second portion SP2 in FIG. 7C but may be configured in three protrusions.

In an embodiment, a shape and/or a surface area of each of the through-holes HLb and HLc in FIGS. 9B and 9C on a plane may be the same as or may be different from the shape and/or the surface area of the through-hole HL in FIG. 7A, and may not be necessarily limited to any shape and/or surface area. FIGS. 9B and 9C illustrate the through-holes HLb and HLc as passing through all of first conductive patterns CL1b and CL1c and pad insulation layers IL-P. However, embodiments of the present inventive concept are not necessarily limited thereto and the through-holes HLb and HLc may pass through only the first conductive patterns CL1b and CL1c in some embodiments.

Referring to FIGS. 9D and 9E, cases in which shapes of through-holes HLd and HLe in a cross-sectional view are not rectangular are illustrated as examples. As illustrated in FIG. 9D, in an embodiment the shape of the through-hole HLd in a cross-sectional view may be an inverted trapezoidal shape. Accordingly, a first portion SP1d of an insulation pattern SPd may have the same shape as the first portion SP1 in FIG. 7C, but a second portion SP2d may correspond to the through-hole HLd to have an inverted trapezoidal shape in a cross-sectional view. As illustrated in FIG. 9E, in an embodiment the shape of the through-hole HLe in a cross-sectional view may be a trapezoidal shape. Accordingly, a first portion SP1e of an insulation pattern SPe may have the same shape as the first portion SP1 in FIG. 7C, but a second portion SP2e may correspond to the through-hole HLe to have a trapezoidal shape in a cross-sectional view.

FIGS. 9D and 9E illustrate the through-holes HLd and HLe as passing through all of first conductive patterns CL1d and CL1e and pad insulation layers IL-P. However, embodiments of the present inventive concept are not necessarily limited thereto and the through-holes HLd and HLe may pass through only the first conductive patterns CL1d and CL1e in some embodiments.

According to the description above, as the bonding area of the insulation pattern is increased, the display panel according to an embodiment of the present inventive concept may reduce the risk of the loss of the insulation pattern and increase the height of the insulation pattern, and the display panel may be reused.

Moreover, the display device including the display panel according to an embodiment of the present inventive concept may increase the contact, and thus the bonding reliability may be increased.

Although non-limiting embodiments of the present inventive concept have been described, it is understood that the present inventive concept should not be limited to the described embodiments but various changes and modifications can be made by one ordinary skilled in the art within the spirit and scope of the present inventive concept. Therefore, the technical scope of embodiments of the present inventive concept is not limited to the described embodiments in the detailed description of the specification.

What is claimed is:

1. A display panel comprising:
a pixel;
a signal line electrically connected to the pixel; and
a signal pad connected to the signal line,
wherein the signal pad includes:
a first conductive pattern connected to an end portion of the signal line;
a second conductive pattern disposed on the first conductive pattern; and
an insulation pattern disposed between the first conductive pattern and the second conductive pattern,
wherein a first through-hole is defined in the first conductive pattern,
wherein the insulation pattern extends into the first through-hole.

2. The display panel of claim 1, wherein an entirety of the insulation pattern is disposed inside each of the first conductive pattern and the second conductive pattern on a plane.

3. The display panel of claim 1, wherein:
the second conductive pattern directly contacts a first portion of the first conductive pattern that does not overlap the insulation pattern on a plane and a top surface of the insulation pattern.

4. The display panel of claim 1, wherein the first through-hole overlaps the insulation pattern on a plane.

5. The display panel of claim 1, wherein the insulation pattern comprises a polymer.

6. The display panel of claim 1, further comprising:
a pad insulation layer disposed between the end portion of the signal line and the first conductive pattern,
wherein a second through-hole extending from the first through-hole is defined in the pad insulation layer,
wherein the insulation pattern extends into the second through-hole.

7. The display panel of claim 1, wherein the first through-hole includes a plurality of first through-holes.

8. A display panel comprising:
a pixel;
a signal line electrically connected to the pixel; and
a signal pad connected to the signal line,
wherein the signal pad includes:
a first conductive pattern connected to an end portion of the signal line;
a second conductive pattern disposed on the first conductive pattern; and
an insulation pattern, wherein an entirety of the insulation pattern is disposed inside each of the first conductive pattern and the second conductive pattern on a plane,
wherein the insulation pattern includes:
a first portion disposed between the first conductive pattern and the second conductive pattern; and
a second portion protruding from the first portion in a direction away from an upper surface of the second conductive pattern.

9. The display panel of claim 8, wherein:
a first through-hole is defined in the first conductive pattern,
wherein the second portion of the insulation pattern is disposed inside the first through-hole.

10. The display panel of claim 8, wherein the second conductive pattern directly contacts a first portion of the first conductive pattern that does not overlap the insulation pattern on a plane and a top surface of the insulation pattern.

11. The display panel of claim 8, wherein the insulation pattern comprises a polymer.

12. The display panel of claim 9, wherein the first through-hole overlaps the insulation pattern on a plane.

13. The display panel of claim 8, further comprising a pad insulation layer disposed between the end portion of the signal line and the first conductive pattern,
wherein a second through-hole extending from the first through-hole is defined in the pad insulation layer,
wherein the second portion of the insulation pattern extends into the second through-hole.

14. The display panel of claim 9, wherein the first through-hole includes a plurality of first through-holes.

15. An electronic apparatus comprising:
a display panel comprising a signal pad;
an electronic component electrically connected to the display panel; and
an adhesive layer bonding the display panel and the electronic component to each other,
wherein the signal pad includes:
a first conductive pattern having a first through-hole defined therein;
a second conductive pattern disposed on the first conductive pattern; and
an insulation pattern disposed between the first conductive pattern and the second conductive pattern,
wherein the first through-hole overlaps the insulation pattern on a plane.

16. The electronic apparatus of claim 15, wherein the insulation pattern extends into the first through-hole.

17. The electronic apparatus of claim 15, wherein:
an entirety of the insulation pattern is disposed inside each of the first conductive pattern and the second conductive pattern on a plane; and
the insulation pattern comprises a polymer.

18. The electronic apparatus of claim 15, wherein the second conductive pattern directly contacts a first portion of the first conductive pattern that does not overlap the insulation pattern on a plane and a top surface of the insulation pattern.

19. The electronic apparatus of claim 15, further comprising a pad insulation layer disposed below the first conductive pattern,
wherein a second through-hole extending from the first through-hole is defined in the pad insulation layer,
wherein the insulation pattern extends into the second through-hole.

20. The electronic apparatus of claim 15, wherein the first through-hole includes a plurality of first through-holes.
